(19) United States
(12) Patent Application Publication
(10) Pub. No.: US 2019/0346130 A1
(43) Pub. Date: Nov. 14, 2019

(54) LIGHT-EMITTING COOLING FAN

(71) Applicant: THERMALTAKE TECHNOLOGY CO., LTD., Taipei City (TW)

(72) Inventor: PEI-HSI LIN, TAIPEI CITY (TW)

(21) Appl. No.: 16/029,727

(22) Filed: Jul. 9, 2018

(30) Foreign Application Priority Data
May 10, 2018 (TW) 107206120

(51) Int. Cl. F21V 33/00; F21V 8/00; F21V 11/16; H05K 1/18; H05K 7/20; F04D 29/00

(52) U.S. Cl. CPC F21V 33/0096; G02B 6/0076; G02B 6/009; F21V 33/0092; F21V 11/16; F21Y 2115/10; G02B 6/0088; H05K 7/20172; F04D 29/005; H05K 2201/10106; H05K 2201/09018; H05K 1/181

(57) ABSTRACT

A light-emitting cooling fan has a fan frame having a frame body and a shaft seat, the frame body having an upper edge and a lower edge, the shaft seat being disposed in the frame body; a motor pivotally disposed on the shaft seat; a blade disposed on the motor; an upper light-guiding ring disposed in the frame body and at the upper edge of the frame body; a plurality of upper light-emitting units disposed in the frame body, spaced apart, and adapted to illuminate the upper light-guiding ring; a lower light-guiding ring disposed in the frame body and at the lower edge of the frame body; and a plurality of lower light-emitting units disposed in the frame body, spaced apart from the upper light-emitting units, and arranged to alternate with the upper light-emitting units, respectively, wherein the lower light-emitting units are higher than the upper light-emitting units, respectively.

### CROSS-REFERENCE TO RELATED APPLICATION

This non-provisional application claims priority under 35 U.S.C. § 119(a) on Patent Application No(s).107206120 filed in Taiwan, R.O.C. on May 10, 2018, the entire contents of which are hereby incorporated by reference.

### TECHNICAL FIELD

The present disclosure relates to light-emitting cooling fans and, more particularly, to a light-emitting cooling fan capable of emitting light in two different light emission modes simultaneously.

### RELATED ART

A cooling fan is a conventional means of dissipating heat from electronic devices. Blades of the cooling fan rotate to generate air currents for removing heat from the electronic devices in operation, so as to achieve heat dissipation. Some conventional cooling fans are equipped with light-emitting components which emit light and thus render the cooling fans visually attractive. However, these conventional cooling fans emit light in one light emission mode only. In the situation where these conventional cooling fans are each equipped with two light-emitting components emitting light in their respective light emission modes (for example, flashing mode and non-flashing mode) or in their respective colors, simultaneous operations of the two light-emitting components lead to the mutual interference between and the mixing of light rays emitted therefrom, thereby blurring the distinction between the two otherwise discernible light emission modes.

### SUMMARY

In view of the aforesaid drawbacks of the prior art, it is an objective of the present disclosure to provide a light-emitting cooling fan, comprising: a fan frame comprising a frame body and a shaft seat, the frame body having an upper edge and a lower edge, the upper edge being parallel to the lower edge, the shaft seat being disposed in the frame body; a motor pivotally disposed on the shaft seat of the fan frame; a blade disposed on the motor; an upper light-guiding ring disposed in the frame body and at the upper edge of the frame body; a plurality of upper light-emitting units disposed in the frame body, spaced apart, and adapted to illuminate the upper light-guiding ring; a lower light-guiding ring disposed in the frame body and at the lower edge of the frame body; and a plurality of lower light-emitting units disposed in the frame body, spaced apart from the upper light-emitting units, and arranged to alternate with the upper light-emitting units, respectively, wherein the lower light-emitting units are higher than the upper light-emitting units, respectively, and illuminate the lower light-guiding ring.

Regarding the light-emitting cooling fan, the upper light-emitting units are spaced apart from the upper light-guiding ring, and the lower light-emitting units are spaced apart from the lower light-guiding ring.

The light-emitting cooling fan further comprises a plurality of light-blocking elements each disposed in the frame body and between an adjacent one of upper light-emitting units and an adjacent one of lower light-emitting units to block not only light emitted from the lower light-emitting units near the light-blocking elements toward the upper light-emitting units near the light-blocking elements but also light emitted from the upper light-emitting units near the light-blocking elements toward the lower light-emitting units near the light-blocking elements.

The light-emitting cooling fan further comprises a circuit board disposed in the frame body and between the upper edge and the lower edge of the frame body, wherein the upper light-emitting units and the lower light-emitting units are disposed on the circuit board.

The light-emitting cooling fan further comprises a shaft seat light-guiding ring and a central light-emitting source. The shaft seat light-guiding ring is disposed on the shaft seat of the fan frame. The central light-emitting source is disposed on the shaft seat and illuminates the shaft seat light-guiding ring.

Regarding the light-emitting cooling fan, the upper light-emitting units and the lower light-emitting units are LED lamps.

Therefore, light rays emitted from two light-emitting units disposed on the light-emitting cooling fan do not interfere with each other, allowing the light-emitting cooling fan to emit light in two different light emission modes simultaneously.

### BRIEF DESCRIPTION OF THE DRAWINGS

FIG. 1 is an exploded view of a light-emitting cooling fan according to the first embodiment of the present disclosure;

FIG. 2 is an exploded view of the light-emitting cooling fan according to the second embodiment of the present disclosure;

FIG. 3 is a partial schematic view of the light-emitting cooling fan according to the second embodiment of the present disclosure;

FIG. 4 is an exploded view of the light-emitting cooling fan according to the third embodiment of the present disclosure;

FIG. 5 is a partial schematic view of the light-emitting cooling fan according to the third embodiment of the present disclosure; and

FIG. 6 is an exploded view of the light-emitting cooling fan according to the fourth embodiment of the present disclosure.

### DETAILED DESCRIPTION OF THE PREFERRED EMBODIMENTS

Objectives, features, and advantages of the present disclosure are hereunder illustrated with specific embodiments in conjunction with the accompanying drawings and described below.

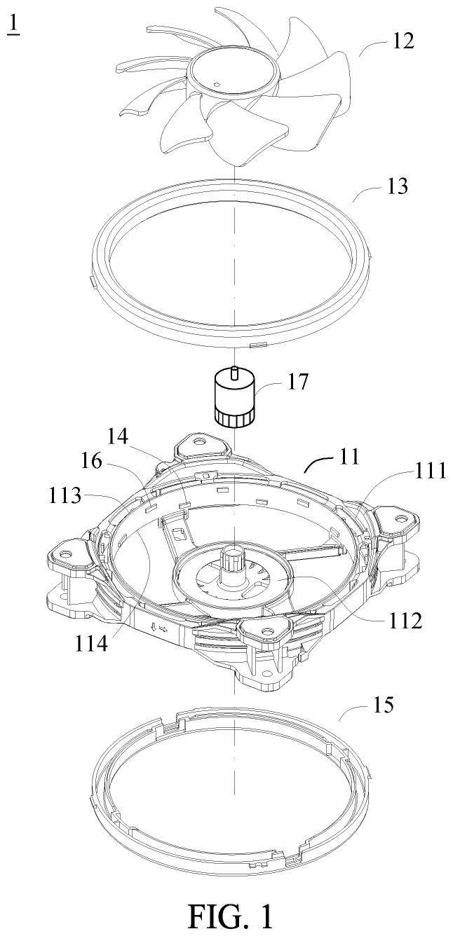

Referring to FIG. 1, a light-emitting cooling fan 1 provided in the first embodiment of the present disclosure comprises a fan frame 11, a motor 17, a blade 12, an upper light-guiding ring 13, a plurality of upper light-emitting units 14, a lower light-guiding ring 15 and a plurality of lower light-emitting units 16. The fan frame 11 comprises a frame body 111 and a shaft seat 112. The frame body 111 has an upper edge 113 and a lower edge 114. The upper edge 113 and the lower edge 114 are parallel. The shaft seat 112 is disposed in the frame body 111. In the first embodiment, the shaft seat 112 is coupled to the frame body 111 by a plurality of ribs and thus disposed in the frame body 111. In a variant embodiment, the shaft seat 112 is disposed in the frame body 111 by another other means; for example, the shaft seat 112 is coupled to the frame body 111 by a plurality of plates. The motor 17 is pivotally disposed on the shaft seat 112 of the fan frame 11. The blade 12 is disposed on the motor. The upper light-guiding ring 13 is not only disposed on and engaged with the frame body 111 but also disposed at the upper edge 113 of the frame body 111. The upper light-emitting units 14 are mounted on the inner wall of the frame body 111 directly and configured to perform electrically driven light emission. The upper light-emitting units 14 are spaced apart. The upper light-emitting units 14 illuminate the upper light-guiding ring 13. The lower light-guiding ring 15 is not only disposed on and engaged with the frame body 111 but also disposed at the lower edge 114 of the frame body 111. Hence, the lower light-guiding ring 15 and the upper light-guiding ring 13 are spaced apart. The lower light-emitting units 16 are mounted on the inner wall of the frame body 111 directly and configured to perform electrically driven light emission. The lower light-emitting units 16 are spaced apart from the upper light-emitting units 14 and arranged to alternate with the upper light-emitting units, respectively. The lower light-emitting units 16 are higher than the upper light-emitting units 14, respectively. The lower light-emitting units 16 illuminate the lower light-guiding ring 15.

In the first embodiment, the lower light-guiding ring 15 and the upper light-guiding ring 13 are spaced apart to preclude mutual interference between a light ray falling on the upper light-guiding ring 13 and a light ray falling on the lower light-guiding ring 15. The lower light-emitting units 16 are spaced apart from the upper light-emitting units 14 and arranged to alternate with the upper light-emitting units 14, respectively. The lower light-emitting units 16 are higher than the upper light-emitting units 14, respectively, to separate the lower light-emitting units 16 horizontally from the upper light-emitting units 14, respectively, and thus preclude mutual interference between a light ray emitted from the upper light-emitting units 14 and a light ray emitted from the lower light-emitting units 16. Therefore, the light-emitting cooling fan 1 emits light in two different light emission modes simultaneously but without mutual interference. For instance, the upper light-guiding ring 13 is in a colored, flashing light emission mode, whereas the lower light-guiding ring 15 is in a colored, non-flashing light emission mode, and the two light emission modes do not interfere with each other.

In the first embodiment, the upper light-emitting units 14 and the lower light-emitting units 16 are mounted on the inner wall of the frame body 111 directly and thus disposed in the frame body 111. In a variant embodiment, the upper light-emitting units 14 and the lower light-emitting units 16 are disposed in the frame body 111 by another other means and configured to perform electrically driven light emission, without being limited to the first embodiment.

In the first embodiment, the upper light-emitting units 14 and the lower light-emitting units 16 are LED lamps. In a variant embodiment, the upper light-emitting units 14 and the lower light-emitting units 16 are any other type of light-emitting components, such as organic light-emitting diodes, without being limited to the first embodiment.

In the first embodiment, the upper light-emitting units 14 are spaced apart from the upper light-guiding ring 13, and the lower light-emitting units 16 are spaced apart from the lower light-guiding ring 15; hence, light rays emitted from the upper light-emitting units 14 and the lower light-emitting units 16 have a wider range of angles of illumination to ensure uniform brightness of the upper light-guiding ring 13 and the lower light-guiding ring 15. In the first embodiment, the upper light-emitting units 14 and the lower light-emitting units 16 are LED lamps. Light rays emitted from LED lamps are more converged than light rays emitted from conventional lightbulbs; as a result, a light-guiding ring illuminated by LED lamps is predisposed to uneven brightness. In the first embodiment, the upper light-emitting units 14 and the lower light-emitting units 16 are spaced apart from the upper light-guiding ring 13 and the lower light-guiding ring 15, respectively, to mitigate uneven brightness of the light-guiding ring. In a variant embodiment, positions of the upper light-emitting units 14 and positions of the lower light-emitting units 16 are subject to change as needed, as long as the upper light-emitting units 14 and the lower light-emitting units 16 can illuminate the upper light-guiding ring 13 and the lower light-guiding ring 15, respectively, without being limited to the first embodiment.

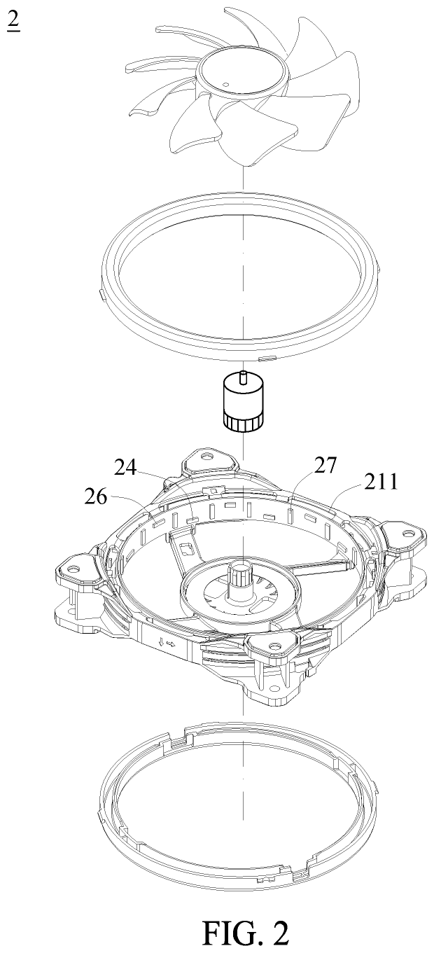

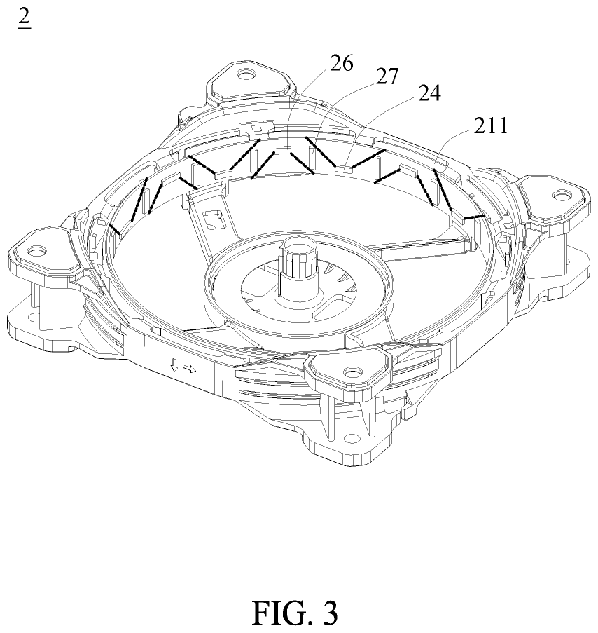

Referring to FIG. 2, a light-emitting cooling fan 2 is provided in the second embodiment of the present disclosure. The light-emitting cooling fan 2 is substantially identical to the light-emitting cooling fan 1 in structures and functions except for its distinguishing technical features described below. The light-emitting cooling fan 2 further comprises a plurality of light-blocking elements 27. The light-blocking elements 27 are disposed in a frame body 211 and between an adjacent one of upper light-emitting units 24 and an adjacent one of lower light-emitting units 26. Referring to FIG. 3, the light-blocking elements 27 each block light emitted from the lower light-emitting units 26 near the light-blocking elements 27 toward the upper light-emitting units 24 near the light-blocking elements 27 but also light emitted from the upper light-emitting units 24 near the light-blocking elements 27 toward the lower light-emitting units 26 near the light-blocking elements 27 so as to further preclude mutual interference between a light ray emitted from the upper light-emitting units 24 and a light ray emitted from the lower light-emitting units 26. In the second embodiment, the light-blocking elements 27 are implemented as upright ribs, have top ends being flush against adjacent ones of the lower light-emitting units 26, and have bottom ends being flush against adjacent ones of the upper light-emitting units 24. In a variant embodiment, the shape of the light-blocking elements 27 as well as the positions of the light-blocking elements 27 relative to adjacent ones of the upper light-emitting units 24 and lower light-emitting units 26 are subject to change as needed, as long as light rays emitted from the adjacent ones of the upper light-emitting units 24 do not fall on the adjacent ones of the lower light-emitting units 26, and vice versa. In the second embodiment, the light-blocking elements 27 are mounted on the inner wall of the frame body 211 directly and thus disposed in the frame body 211. In a variant embodiment, the light-blocking elements 27 are disposed in the frame body 211 by any other means and configured to perform electrically driven light emission, without being limited to the second embodiment.

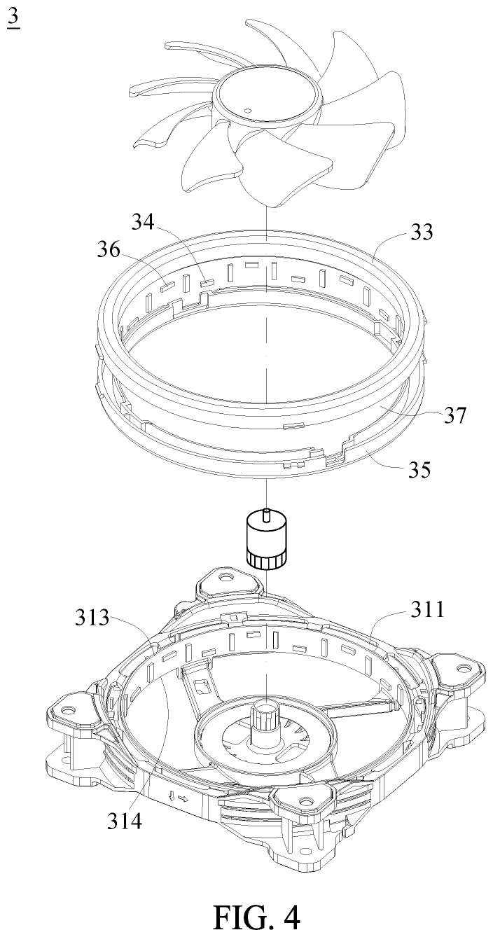

Referring to FIG. 4, a light-emitting cooling fan 3 is provided in the third embodiment of the present disclosure. The light-emitting cooling fan 3 is substantially identical to the light-emitting cooling fan 2 in structures and functions except for its distinguishing technical features described below. The light-emitting cooling fan 3 comprises upper light-emitting units 34 and lower light-emitting units 36 which are mounted on a ring-shaped circuit board 37, and then the circuit board 37 is fitted between an upper light-guiding ring 33 and a lower light-guiding ring 35, such that the upper light-guiding ring 33, the circuit board 37 and the lower light-guiding ring 35 jointly form a ring-shaped structure. Afterward, the ring-shaped structure is disposed in a frame body 311 such that the circuit board 37 and the upper and lower light-emitting units 34, 36 mounted on the circuit board 37 are disposed between an upper edge 313 and a lower edge 314.

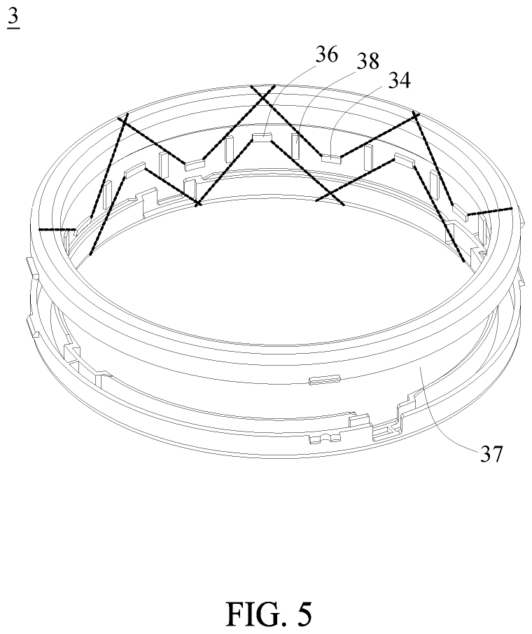

Referring to FIG. 5, the light-emitting cooling fan 3 comprises light-blocking elements 38 for preventing light rays emitted from the upper light-emitting units 34 from falling on the lower light-emitting units 36 and light rays emitted from the lower light-emitting units 36 from falling on the upper light-emitting units 34. The light-blocking elements 38 are mounted on the circuit board 37 and thus disposed in the frame body 311.

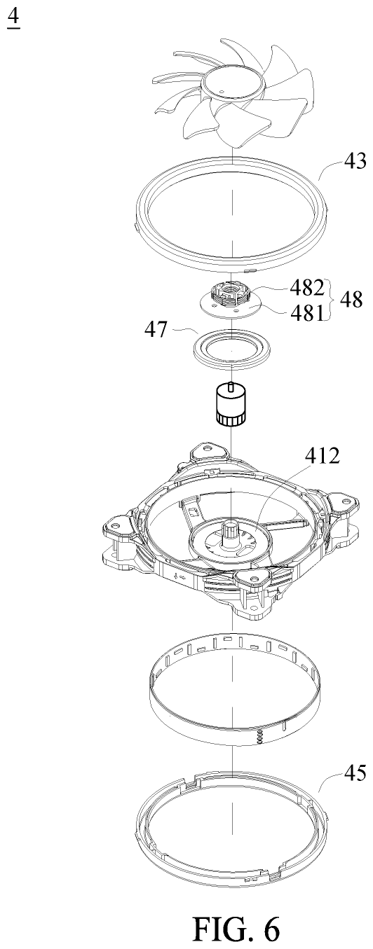

Referring to FIG. 6, a light-emitting cooling fan 4 is provided in the fourth embodiment of the present disclosure. The light-emitting cooling fan 4 is substantially identical to the light-emitting cooling fan 3 in structures and functions except for its distinguishing technical features described below. The light-emitting cooling fan 4 further comprises a shaft seat light-guiding ring 47 and a central light-emitting source 48. The shaft seat light-guiding ring 47 is disposed on a shaft seat 412. The central light-emitting source 48 is disposed on the shaft seat 412 and adapted to illuminate the shaft seat light-guiding ring 47. The central light-emitting source 48 comprises a circuit board 481 and a plurality of central light-emitting units 482. The central light-emitting units 482 are disposed on the circuit board 481, and then the circuit board 481 is disposed on the shaft seat 412. In a variant embodiment, the central light-emitting units 482 are disposed on the shaft seat 412 by any other means or mounted on the shaft seat 412 directly and configured to perform electrically driven light emission. Alternatively, the central light-emitting source 48 only includes a single central light-emitting unit 482, without being limited to the third embodiment. Owing to the shaft seat light-guiding ring 47 and the central light-emitting source 48, it is feasible for a third light emission mode to be provided at the center of the front of the light-emitting cooling fan 3 without interfering mutually with the light emission modes presented on an upper light-guiding ring 43 and a lower light-guiding ring 45.

The light-emitting cooling fans in the aforesaid embodiments have advantageous technical features as follows: the lower light-guiding ring and the upper light-guiding ring are spaced apart; the lower light-emitting units are spaced apart from the upper light-emitting units and arranged to alternate with the upper light-emitting units, respectively; and the lower light-emitting units are higher than the upper light-emitting units, respectively. Therefore, the aforesaid light-emitting cooling fans emit light in two different light emission modes simultaneously but without mutual interference. In the aforesaid embodiments, the upper light-emitting units are spaced apart from the upper light-guiding ring, whereas the lower light-emitting units are spaced apart from the lower light-guiding ring, so as to ensure uniform brightness of the upper light-guiding ring and the lower light-guiding ring. The light-blocking elements further prevent a light ray emitted from the upper light-emitting units from interfering with a light ray emitted from the lower light-emitting units, and vice versa. In the aforesaid embodiments, owing to the shaft seat light-guiding ring and the central light-emitting source, it is feasible for a third light emission mode to be provided at the center of the front of the light-emitting cooling fan without interfering mutually with the light emission modes presented on the upper light-guiding ring and the lower light-guiding ring.

The present disclosure is disclosed above by preferred embodiments. However, persons skilled in the art should understand that the preferred embodiments are illustrative of the present disclosure only, but shall not be interpreted as restrictive of the scope of the present disclosure. Hence, all equivalent modifications and replacements made to the aforesaid embodiments shall fall within the scope of the present disclosure. Accordingly, the legal protection for the present disclosure shall be defined by the appended claims.

What is claimed is:

1. A light-emitting cooling fan, comprising:
a fan frame comprising a frame body and a shaft seat, the frame body having an upper edge and a lower edge, the upper edge being parallel to the lower edge, the shaft seat being disposed in the frame body;
a motor pivotally disposed on the shaft seat of the fan frame;
a blade disposed on the motor;
an upper light-guiding ring disposed in the frame body and at the upper edge of the frame body;
a plurality of upper light-emitting units disposed in the frame body, spaced apart, and adapted to illuminate the upper light-guiding ring;
a lower light-guiding ring disposed in the frame body and at the lower edge of the frame body; and
a plurality of lower light-emitting units disposed in the frame body, spaced apart from the upper light-emitting units, and arranged to alternate with the upper light-emitting units, respectively, wherein the lower light-emitting units are higher than the upper light-emitting units, respectively, and illuminate the lower light-guiding ring.

2. The light-emitting cooling fan of claim 1, wherein the upper light-emitting units are spaced apart from the upper light-guiding ring, and the lower light-emitting units are spaced apart from the lower light-guiding ring.

3. The light-emitting cooling fan of claim 1, further comprising a plurality of light-blocking elements each disposed in the frame body and between an adjacent one of upper light-emitting units and an adjacent one of lower light-emitting units to block not only light emitted from the lower light-emitting units near the light-blocking elements toward the upper light-emitting units near the light-blocking elements but also light emitted from the upper light-emitting units near the light-blocking elements toward the lower light-emitting units near the light-blocking elements.

4. The light-emitting cooling fan of claim 2, further comprising a plurality of light-blocking elements each disposed in the frame body and between an adjacent one of upper light-emitting units and an adjacent one of lower light-emitting units to block not only light emitted from the lower light-emitting units near the light-blocking elements toward the upper light-emitting units near the light-blocking elements but also light emitted from the upper light-emitting units near the light-blocking elements toward the lower light-emitting units near the light-blocking elements.

5. The light-emitting cooling fan of claim 1, further comprising a circuit board disposed in the frame body and between the upper edge and the lower edge of the frame body, wherein the upper light-emitting units and the lower light-emitting units are disposed on the circuit board.

6. The light-emitting cooling fan of claim 2, further comprising a circuit board disposed in the frame body and between the upper edge and the lower edge of the frame body, wherein the upper light-emitting units and the lower light-emitting units are disposed on the circuit board.

7. The light-emitting cooling fan of claim 1, further comprising a shaft seat light-guiding ring and a central light-emitting source, with the shaft seat light-guiding ring disposed on the shaft seat of the fan frame, and the central light-emitting source disposed on the shaft seat to illuminate the shaft seat light-guiding ring.

8. The light-emitting cooling fan of claim 2, further comprising a shaft seat light-guiding ring and a central light-emitting source, with the shaft seat light-guiding ring disposed on the shaft seat of the fan frame, and the central light-emitting source disposed on the shaft seat to illuminate the shaft seat light-guiding ring.

9. The light-emitting cooling fan of claim 1, wherein the upper light-emitting units and the lower light-emitting units are LED lamps.

10. The light-emitting cooling fan of claim 2, wherein the upper light-emitting units and the lower light-emitting units are LED lamps.

11. The light-emitting cooling fan of claim 3, further comprising a circuit board disposed in the frame body and between the upper edge and the lower edge of the frame body, wherein the upper light-emitting units and the lower light-emitting units are disposed on the circuit board.

12. The light-emitting cooling fan of claim 3, further comprising a shaft seat light-guiding ring and a central light-emitting source, with the shaft seat light-guiding ring disposed on the shaft seat of the fan frame, and the central light-emitting source disposed on the shaft seat to illuminate the shaft seat light-guiding ring.

13. The light-emitting cooling fan of claim 3, wherein the upper light-emitting units and the lower light-emitting units are LED lamps.

14. The light-emitting cooling fan of claim 11, further comprising a shaft seat light-guiding ring and a central light-emitting source, with the shaft seat light-guiding ring disposed on the shaft seat of the fan frame, and the central light-emitting source disposed on the shaft seat to illuminate the shaft seat light-guiding ring.
